(19) United States
(12) Patent Application Publication
(10) Pub. No.: US 2026/0089965 A1
(43) Pub. Date: Mar. 26, 2026

(54) SEMICONDUCTOR STRUCTURE AND METHOD FOR FORMING THE SAME

(71) Applicant: TAIWAN SEMICONDUCTOR MANUFACTURING COMPANY LTD., HSINCHU (TW)

(72) Inventors: YEN-CHIEH HUANG, CHANGHUA COUNTY (TW); HUAI-YING HUANG, NEW TAIPEI CITY (TW); YU-MING LIN, HSINCHU CITY (TW); CHUN-CHIEH LU, TAIPEI CITY (TW); YU-CHUAN SHIH, HSINCHU CITY (TW); HAO-KAI PENG, HSINCHU (TW)

(21) Appl. No.: 18/894,028

(22) Filed: Sep. 24, 2024

(51) Int. Cl. H10B 51/20; H01L 21/28; H01L 29/51; H01L 29/66; H01L 29/78; H10B 51/10

(52) U.S. Cl. CPC H10B 51/20; H10B 51/10; H10D 30/0415; H10D 30/701; H10D 64/033; H10D 64/689

(57) ABSTRACT

A semiconductor structure includes a gate electrode, a ferroelectric layer over the gate electrode, a channel structure over the ferroelectric layer, a source electrode and a drain electrode over the ferroelectric layer, a first multilayered structure, and a second multilayered structure. The first multilayered structure is disposed between the source electrode and the channel structure, and the second multilayered structure is disposed between the drain electrode and the channel structure. The channel structure includes a first channel layer over the ferroelectric layer and a second channel layer between the first channel layer and the ferroelectric layer. A donor carrier concentration of the first channel layer is different from a donor carrier concentration of the second channel layer.

### BACKGROUND

A ferroelectric field-effect transistor (FeFET) device is a type of ferroelectric random-access memory (FeRAM) device including a ferroelectric material arranged between a conductive gate structure and a channel region disposed between a source region and a drain region. During operation of a FeFET device, an application of a gate voltage to the gate structure generates an electric field that causes a dipole moment to form within the ferroelectric material. Depending on a value of the gate voltage, a direction of the dipole moment (i.e., a polarization) may be one of two opposing directions. Since a threshold voltage (e.g., a minimum gate-to-source voltage that forms a conductive path between the source region and the drain region) of a FeFET device is dependent upon the polarization within the ferroelectric material, the different polarizations effectively split the threshold voltage of the FeFET device into two distinct values corresponding to different data states.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flowchart representing a method for forming a semiconductor memory structure according to aspects of the present disclosure.

FIGS. 2A to 2J are schematic drawings illustrating a semiconductor memory structure at various fabrication stages constructed according to aspects of the present disclosure in one or more embodiments.

FIG. 3 is a schematic cross-sectional view illustrating a semiconductor memory structure according to aspects of the present disclosure in one or more embodiments.

FIG. 4 is a schematic cross-sectional view illustrating a semiconductor memory structure according to aspects of the present disclosure in one or more embodiments.

FIG. 5 is a schematic cross-sectional view illustrating a semiconductor memory structure according to aspects of the present disclosure in one or more embodiments.

FIG. 6 is a schematic cross-sectional view illustrating a semiconductor memory structure according to aspects of the present disclosure in one or more embodiments.

FIG. 7 is a schematic cross-sectional view illustrating a semiconductor memory structure according to aspects of the present disclosure in one or more embodiments.

FIG. 8 is a plan view of the semiconductor memory structure of FIGS. 21 and 3 to 6 according to aspects of the present disclosure in one or more embodiments.

FIG. 9 is a flowchart representing a method for forming a semiconductor memory structure according to aspects of the present disclosure.

FIGS. 10A to 10P are schematic drawings illustrating a semiconductor memory structure at various fabrication stages constructed according to aspects of the present disclosure in one or more embodiments.

FIG. 11 is a schematic cross-sectional view illustrating a semiconductor memory structure according to aspects of the present disclosure in one or more embodiments.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

Polarizations with different polarities stored in a ferroelectric material of a ferroelectric memory may affect a threshold voltage of the ferroelectric memory, and such polarizations can be non-destructively read out by sensing a channel resistance of the ferroelectric memory. However, an interface defined between the ferroelectric material and a channel region is susceptible to defect formation. Performance of the ferroelectric memory may be accordingly influenced by such defects.

The present disclosure therefore provides a semiconductor memory structure and a method for forming the same. In some embodiments, the semiconductor memory structure may be a ferroelectric memory formed in a back-end-of-line (BEOL) interconnect structure. In some embodiments, the semiconductor memory structure may include a bi-layered structure or a multilayered structure serving as a channel layer. In some embodiments, the bi-layered or multilayered channel layer includes at least a pair of layers, including a first layer having a high donor carrier concentration and a second layer having a low donor carrier concentration. A mobility is therefore improved to mitigate defect issues, and thus an on current (Ion) is increased by the bi-layered or multilayered channel layer. In some embodiments, the semiconductor memory structure may include a multilayered structure disposed in a source/drain region. The multilayered structure serves as a quantum well and improves an electron confinement effect on the source/drain regions. Accordingly, the mobility and the on current are further increased.

In some embodiments, the ferroelectric memory provided by the present disclosure may be a planar device. In other embodiments, the ferroelectric memory provided by the present disclosure may have a 3D configuration.

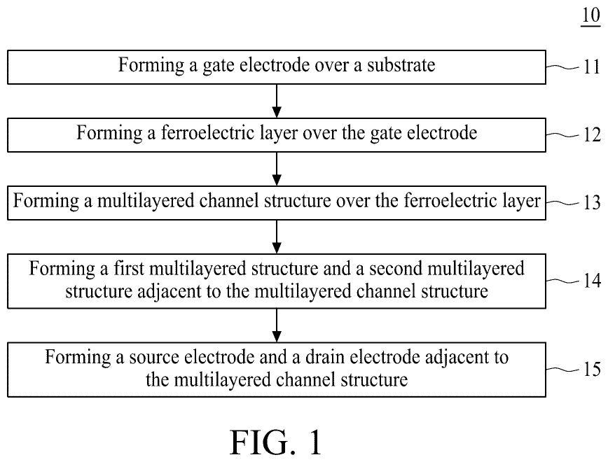

FIG. 1 is a flowchart representing a method for forming a semiconductor memory structure 10 in accordance with aspects of the present disclosure. The method 10 includes a number of operations (11, 12, 13, 14 and 15). The method 10 will be further described according to one or more embodiments. It should be noted that the operations of the method 10 may be rearranged or otherwise modified within the scope of the various aspects. It should be further noted that additional processes may be provided before, during, and after the method 10, and that some other processes may be only briefly described herein. Thus, other implementations are possible within the scope of the various aspects described herein.

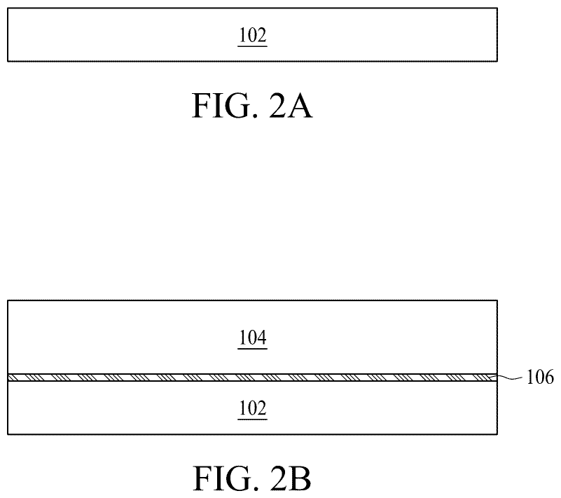

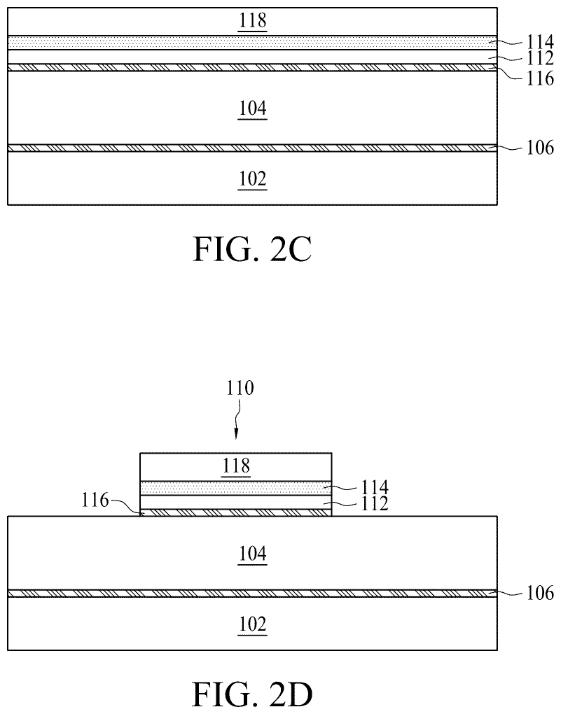

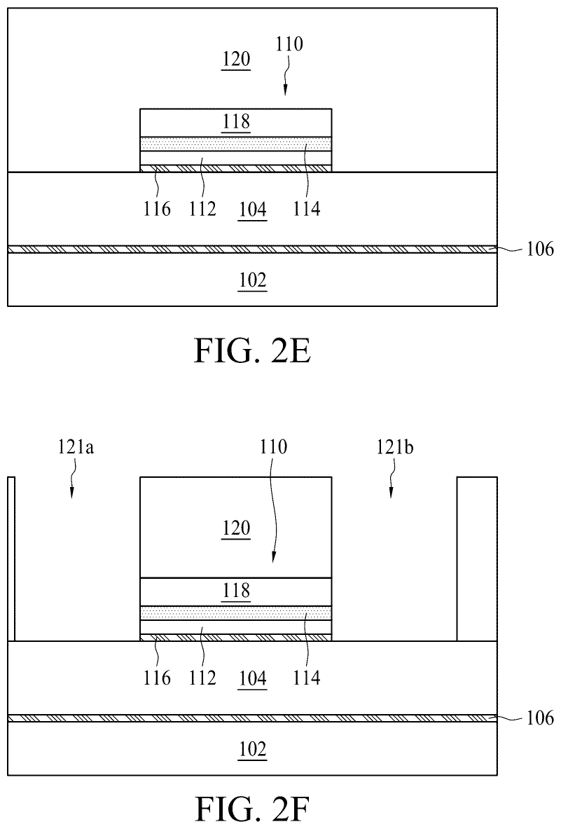

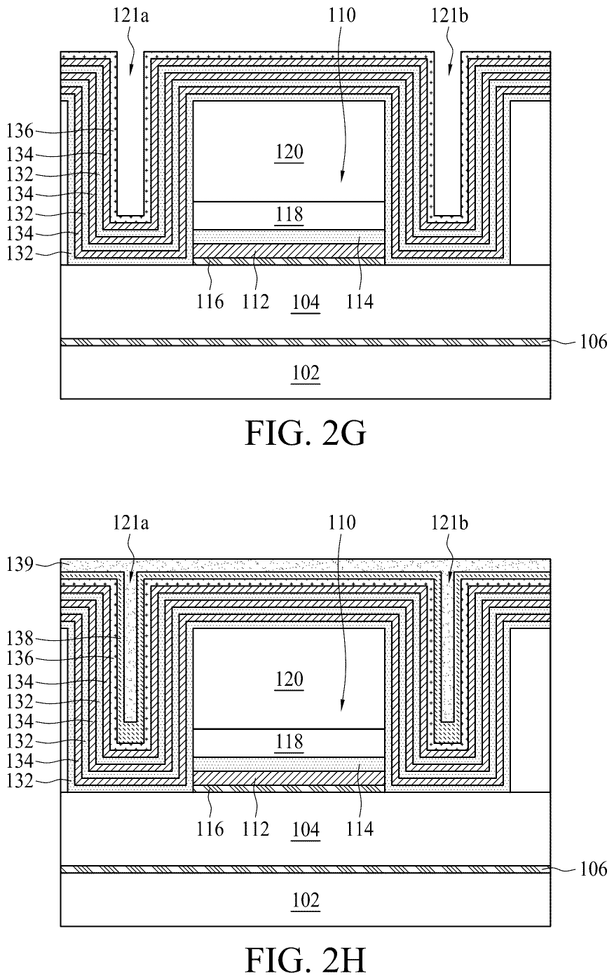

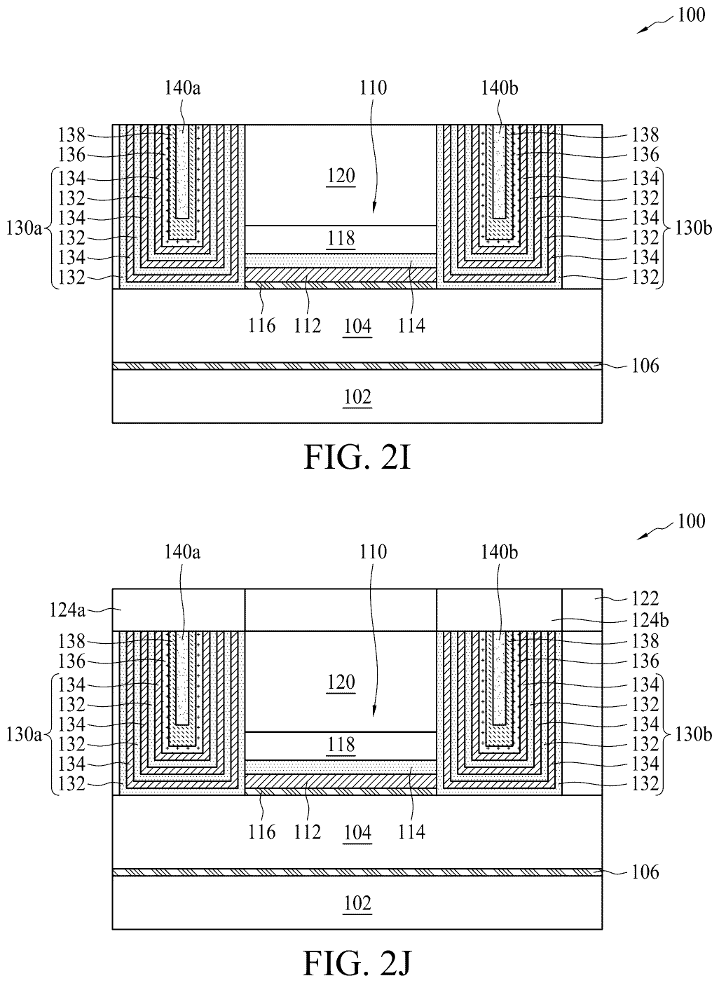

In some embodiments, a semiconductor memory structure 100 may be formed by the method 10. FIGS. 2A to 2J are schematic drawings illustrating the semiconductor memory structure 100 at various fabrication stages constructed according to aspects of the present disclosure in one or more embodiments.

For example, referring to FIG. 2A, in some embodiments, in operation 11, a gate electrode 102 is formed over a substrate. In some embodiments, the substrate (not shown) may be any type of semiconductor body (including, for example, silicon (Si), silicon germanium (SiGe), silicon-on-insulator (SOI), or like), such as a semiconductor wafer and/or one or more dies on a wafer, as well as any other type of semiconductor and/or epitaxial layers, suitable for such application. In some embodiments, a dielectric structure (not shown) may be formed over the substrate, and the gate electrode 102 may be formed in the dielectric structure over the substrate. In some embodiments, the gate electrode 102 is formed in a dielectric structure of a back-end-of-line (BEOL) structure of a device die. A front-end-of-line (FEOL) structure (not shown) including active devices (e.g., metal-oxide-semiconductor (MOS) FETs) formed on the substrate (e.g., a semiconductor wafer) lies below the BEOL structure, and some conductive features in the BEOL structure interconnect the underlying active devices, to form an integrated circuit. In such embodiments, the gate electrode 102 may be formed in one of a stack of dielectric layers in the BEOL structure.

In some embodiments, the gate electrode 102 may include a conductive material. In some embodiments, the conductive material of the gate electrode 102 may have a metal work function that is configured to increase a threshold voltage of the semiconductor memory structure 100, thereby further mitigating a current flowing through a channel region. In some embodiments, the gate electrode 102 may include platinum (Pt), titanium (Ti), titanium nitride (TiN), tantalum (Ta), tantalum nitride (TaN), tungsten (W), tungsten nitride (WN), copper (Cu), gold (Au), zinc (Zn), aluminum (Al), iron (Fe), nickel (Ni), beryllium (Be), chromium (Cr), cobalt (Co), antimony (Sb), iridium (Ir), molybdenum (Mo), osmium (Os), thorium (Th), vanadium (V), or a combination thereof. In some embodiments, the gate electrode 102 may include a buried gate structure, but the disclosure is not limited thereto. In such embodiments, a top surface of the gate electrode 102 may be aligned with (i.e., coplanar with) a top surface of the substrate or a top surface of the dielectric structure, but the disclosure is not limited thereto. In some embodiments, a thickness of the gate electrode 102 may be between approximately 50 nanometers and approximately 10,000 nanometers, but the disclosure is not limited thereto. In various embodiments, the gate electrode 102 may be formed by way of one or more deposition processes (e.g., atomic layer deposition (ALD) processes, chemical vapor deposition (CVD) processes, plasma-enhanced chemical vapor deposition (PE-CVD) processes, or the like), and various patterning processes.

Referring to FIG. 2B, in some embodiments, in operation 12, a ferroelectric layer 104 is formed over the gate electrode 102. The ferroelectric layer 104 includes a material having dielectric crystals which exhibit an electric polarization having a direction that can be controlled by an electric field. For example, in some embodiments, the ferroelectric layer 104 may include hafnium oxide (HfO₂), hafnium zinc oxide (HfZnO₂), zinc oxide (ZnO), Zr-doped HfO₂, Al-doped HfO₂, Sc-doped TiN, potassium nitrate (KNO₃), bismuth ferrite (BiFeO₃), bismuth manganite (BiMnO₃), yttrium manganite (YMnO₃), terbium manganite (TbMnO₃), lead zirconate titanate (also known as lead zirconium titanate) (Pb[ZrₓTi₁₋ₓ]O₃(0≤x≤1), Pb(Zr, Ti)O₃, PZT), Pb(Sc_{0.5}Ta_{0.5})O₃, Pb(Sc_{0.5}Nb_{0.5})O₃, Pb(Mg_{1/3}Nb_{2/3})O₃, Pb(Zn_{1/3}Nb_{2/3})O₃, lithium tantalate (LiTaO₃), lithium niobate (LiNbO₃), strontium bismuth tantalate, (Sr_{0.8}Bi₂Ta_{2.2}O₉SBT), strontium bismuth niobium oxide (SrBi₂Nb₂O₉, SBN), lead titanate (PbTiO₃), barium titanate (BaTiO₃), lithium titanate (LiTiO₃), lithium niobate (LiNbO₃), BeFeO₃, potassium niobate (KNbO₃), potassium tantalate (KTaO₃), calcium titanate (CaTiO₃), gadolinium orthoferrite (GdFeO₃), dysprosium scandate (DyScO₃), bismuth tungstate (Bi₂WO₆), bismuth titanate (Bi₄Ti₃O₁₂, BTO), Mn₃TeO₆, lead germanate (Pb₅Ge₃O₁₁), gadolinium molybdate (Gd₂(MoO₄)₃), R₃Sb₅O₁₂ (R=Pr, Nd, Sm, Eu, Gd, Yb), lithium-sodium tetragermanate LiNaGe₄O₉, LNG), barium aluminate (BaAl₂O₄), lithium heptagermanate (Li₂Ge₇O₁₅, LGO), yttrium manganite (YMnO₃), samarium hexaboride (SmB₆), barium bismuthate (BaBiO₃, BBO), lutetium ferrite (LuFe₂O₄), yttrium ferrite (YFe₂O₄), iron borate (Fe₂BO₄), lanthanum strontium nickelate (La_{1.5}Sr_{0.5}NiO₄), or the like. In some embodiments, a thickness of the ferroelectric layer 104 may be between approximately 1 nanometer and approximately 1,000 nanometers, but the disclosure is not limited thereto. In various embodiments, the ferroelectric layer 104 may be formed by way of one or more deposition processes (e.g., ALD, CVD, PECVD, or the like).

In some embodiments, the ferroelectric layer 104 may be in contact with the gate electrode 102. In other embodiments, one or more other layers, such as a buffer layer, a barrier layer, or an interface layer 106, may be disposed between the ferroelectric layer 104 and the gate electrode 102. In some embodiments, the interface layer 106 may include a high-k dielectric layer. In some embodiments, the interface 106 may include a strong bond-energy material layer. In some embodiments, the interface layer 106 may include titanium oxide (TiOₓ), hafnium oxide (HfOₓ), zirconium oxide (ZrOₓ), niobium oxide (NbOₓ), cerium oxide (CeOₓ), or the like, wherein x=0 to 2. In some embodiments, a thickness of the interface layer 106 may be between approximately 0.1 nanometer and approximately 20 nanometers, but the disclosure is not limited thereto.

In some embodiments, in operation 13, a multilayered channel structure 110 is formed over the ferroelectric layer 104. In some embodiments, operation 13 includes further operations. For example, referring to FIG. 2C, a channel layer 112 and a channel layer 114 are sequentially formed over the ferroelectric layer 104. In some embodiments, a thickness of the channel layer 112 is between approximately 1 nanometer and approximately 10 nanometers, and a thickness of the channel layer 114 is between approximately 1 nanometer and approximately 10 nanometers. In some embodiments, the thickness of the channel layer 112 and the thickness of the channel layer 114 may be similar, as shown in FIG. 2C. In some alternative embodiments, the thickness of the channel layer 112 and the thickness of the channel layer 114 are different. A donor carrier (Nd) concentration of the channel layer 112 and a donor carrier concentration of the channel layer 114 are different from each other. In some embodiments, the Nd carrier concentration of the channel layer 112 is greater than the Nd carrier concentration of the channel layer 114. For example, the Nd carrier concentration of the channel layer 112 may be greater than 1E15 cm⁻³, and the Nd carrier concentration of the channel layer 114 is less than 1E15 cm⁻³. In such embodiments, the channel layer 112 may be referred to as a high Nd carrier channel layer, while the channel layer 114 may be referred to as a low Nd carrier channel layer. Further, the thickness of the high Nd carrier channel layer 112 may be greater than the thickness of the low Nd carrier channel layer 114, as shown in FIG. 3. In some embodiments, the high Nd carrier channel layer 112 may include indium gallium zinc oxide (IGZO), (In₂O₃)ₓ—(ZnO)₁₋ₓ (mol %+(ZnO)_{y}—(Ga₂O₃)_{1-y}+(Gz₂O₃)_{z}—(In₂O₃)_{1-z}), wherein x=0.5 to 1, y=0.5 to 1, z=0 to 0.5. In some embodiments, the low Nd carrier channel layer 114 may include IGZO, (In₂O₃)ₓ—(ZnO)₁₋ₓ (mol %+(ZnO)_{y}—(Ga₂O₃)_{1-y}+(Gz₂O₃)_{z}—(In₂O₃)_{1-z}), wherein x=0 to 0.5, y=0 to 0.5, z=0.5 to 1. In some embodiments, the channel layers 112 and 114 may include Si, Ge, C, SiC, SiGe, SiGeC, GaAs, In-rich GaAs (In_{0.65}Ga_{0.35}As), InP, GaP, GaN, GaSb, AlAs, InAs, InSb, AlGaAs, GaInAs, GaInP, InAlAs, InGaAs, AlInGaP, CdS, CdSe, CdTe, ZnS, ZnSe, ZnTe, PbS, PbTe, HgTe, InGaZnO, InOx, GaZnOx, InGaSnOx, SnOx, etc. In some embodiments, a H₂ annealing may be performed after the forming the multilayered channel structure 110. In such embodiments, the H₂ annealing may be performed at a temperature greater than approximately 380° C., but the disclosure is not limited thereto.

Still referring to FIG. 2C, in some embodiments, one or more other layers, such as a buffer layer, a barrier layer, or an interface layer 116, may be disposed between the ferroelectric layer 104 and the channel layer 112. In some embodiments, the interface layer 116 may include a high-k dielectric layer. In some embodiments, the interface 116 may include a strong bond-energy material layer. The interface layer 116 may include TiOₓ, HfOₓ, ZrOₓ, NbOₓ, CeOₓ, or the like, wherein x=0 to 2. In some embodiments, a thickness of the interface layer 116 may be between approximately 0.1 nanometer and approximately 20 nanometers, but the disclosure is not limited thereto.

In some embodiments, a cap layer 118 may be formed over the channel layer 114. The cap layer 118 may include AlO₂ or silicon oxide (SiOₓ), wherein x=0 to 2. In some embodiments, a thickness of the cap layer 118 is between approximately 1 nanometer and approximately 500 nanometers, but the disclosure is not limited thereto. In some embodiments, one or more layers, such as a buffer layer, a barrier layer or an interface layer, may be formed between the channel layer 114 and the cap layer 118, but the disclosure is not limited thereto.

Referring to FIG. 2D, in some embodiments, the cap layer 118, the channel layer 114, the channel layer 112 and the interface layer 116 are patterned to form the multilayered channel structure 110.

In some embodiments, in operation 14, a first multilayered structure 130a and a second multilayered structure 130b are formed adjacent to the multilayered channel structure 110. In some embodiments, operation 14 includes further operations. For example, referring to FIG. 2E, a dielectric structure 120 is formed over the multilayered channel structure 110. The dielectric structure 120 may be formed to entirely cover the multilayered channel structure 110. For example, the dielectric structure 120 covers an upper surface and sidewalls of the multilayered channel structure 110. In some embodiments, a planarization may be performed on the dielectric structure 120 such that the dielectric structure 120 obtains a flush and even surface, as shown in FIG. 2E. In some embodiments, the dielectric structure 120 includes dielectric materials same as those used in the BEOL interconnect structure. In some embodiments, the dielectric structure may be a part of an inter-metal dielectric (IMD) structure. The IMD structure may include one or more dielectric layers, and the dielectric layer may include silicon oxide, silicon nitride, carbon doped silicon dioxide, BSG, PSG, BPSG, FSG, USG, a porous dielectric material, or the like.

Referring to FIG. 2F, a patterning process is performed to pattern the dielectric structure 120. In some embodiments, portions of the dielectric structure 120 are removed to form trenches 121a and 121b for accommodating a source electrode and a drain electrode. In some embodiments, the trenches 121a and 121b respectively penetrate the dielectric structure 120 and expose the sidewalls of the multilayered channel structure 110. Additionally, portions of the dielectric structure 120 are exposed through sidewalls of the trenches 121a and 121b. In some embodiments, portions of the ferroelectric layer 104 are exposed through bottoms of the trenches 121a and 121b.

Referring to FIG. 2G, in some embodiments, a plurality of semiconductor layers 132 and a plurality of semiconductor layers 134 are periodically formed in the trenches 121a and 121b. In some embodiments, the semiconductor layer 132 is in contact with the sidewalls of the multilayered channel structure 110 and the exposed portion of the dielectric structure 120. In some embodiments, the semiconductor layer 132 is also in contact with the ferroelectric layer 104. In some embodiments, a thickness of the semiconductor layer 132 is between approximately 1 nanometer and approximately 10 nanometers, and a thickness of the semiconductor layer 134 is between approximately 1 nanometer and approximately 10 nanometers. In some embodiments, the thickness of the semiconductor layer 132 and the thickness of the semiconductor layer 134 may be similar, as shown in FIG. 2G. In some alternative embodiments, the thickness of the semiconductor layer 132 and the thickness of the semiconductor layer 134 are different. A donor carrier (Nd) concentration of the semiconductor layer 132 and a donor carrier (Nd) concentration of the semiconductor layer 134 are different from each other. In some embodiments, the Nd carrier concentration of the channel layer 132 is less than the Nd carrier concentration of the semiconductor layer 134. For example, the Nd carrier concentration of the semiconductor layer 132 may be less than 1E15 cm⁻³, and the Nd carrier concentration of the semiconductor layer 134 is greater than 1E15 cm⁻³. In such embodiments, the semiconductor layer 132 may be referred to as a low Nd carrier semiconductor layer, while the semiconductor layer 134 may be referred to as a high Nd carrier semiconductor layer. Further, the thickness of the low Nd carrier semiconductor layer 132 is greater than the thickness of the high Nd carrier semiconductor layer 134. In some embodiments, the low Nd carrier semiconductor layer 132 may include indium gallium zinc oxide (IGZO), (In₂O₃)ₓ—(ZnO)₁₋ₓ (mol %+(ZnO)_{y}—(Ga₂O₃)_{1-y}+(Gz₂O₃)₂—(In₂O₃)_{1-z}), wherein x=0 to 0.5, y=0 to 0.5, z=0.5 to 1. In some embodiments, the low Nd carrier semiconductor layer 134 may include IGZO, (In₂O₃)ₓ—(ZnO)₁₋ₓ (mol %+(ZnO)_{y}—(Ga₂O₃)_{1-y}+(Gz₂O₃)_{z}—(In₂O₃)_{1-z}), wherein x=0.5 to 1, y=0.5 to 1, z=0 to 0.5. In some embodiments, the semiconductor layers 132 and 134 may include Si, Ge, C, SiC, SiGe, SiGeC, GaAs, In-rich GaAs (In_{0.65}Ga_{0.35}As), InP, GaP, GaN, GaSb, AlAs, InAs, InSb, AlGaAs, GaInAs, GaInP, InAlAs, InGaAs, AlInGaP, CdS, CdSe, CdTe, ZnS, ZnSe, ZnTe, PbS, PbTe, HgTe, InGaZnO, InOx, GaZnOx, InGaSnOx, SnOx, etc.

In some embodiments, a conductive layer 136 may be formed over the topmost semiconductor layer 134. The conductive layer 136 may include metal oxide such as, for example but not limited thereto, indium zinc oxide (InZnO), indium oxide (InOx), indium gallium zinc oxide (InGaZnO), tin oxide (SnOx), or indium tin oxide (InSnO, ITO). In some embodiments, a thickness of the conductive layer 136 may be between approximately 1 nanometer and approximately 5 nanometers, but the disclosure is not limited thereto. In some embodiments, the conductive layer 136 may be in contact with the semiconductor layer 134. In some alternative embodiments, one or more layers, such as a buffer layer, a barrier layer or an interface layer may be formed between the semiconductor layer 134 and the conductive layer 136, but the disclosure is not limited thereto.

In some embodiments, in operation 15, a source electrode 140a and a drain electrode 140b are formed. In some embodiments, operation 14 and operation 15 may performed together. For example, as shown in FIG. 2H, in some embodiments, after the forming of the semiconductor layers 132 and the semiconductor layers 134, a conductive material 139 is formed to fill the trenches 121a and 121b. In some embodiments, a barrier layer 138 may be formed prior to the forming of the conductive material 139. The barrier layer 138 may include titanium nitride (TiN), tungsten carbonitride (WCN), tungsten nitride (WN), tantalum (Ta), tantalum nitride (TaN) cobalt (Co), or the like. A thickness of the barrier layer 138 may be between approximately 0.5 nanometer and approximately 5 nanometers, but the disclosure is not limited thereto. In some embodiments, the conductive material 139 may include metals such as platinum (Pt), ruthenium (Ru), palladium (Pd), W, or gold (Au), but the disclosure is not limited thereto. In some embodiments, the conductive material 139 may include a conductive material same as that of the gate electrode 102. In other embodiments, the conductive material 139 may include a conductive material different from that of the gate electrode 102.

Referring to FIG. 2I, in some embodiments, a planarization is performed to remove superfluous material, thereby exposing a top surface of the dielectric structure 120. Further, the first multilayered structure 130a, the source electrode 140a, the second multilayered structure 130b and the drain electrode 140b are concurrently formed. In some embodiments, the first multilayered structure 130a surrounds a bottom and sidewalls of the source electrode 140a, and the second multilayered structure 130b surrounds a bottom and sidewalls of the drain electrode 140b. Accordingly, a semiconductor memory structure 100 is formed.

Referring to FIG. 2J, after the forming of the semiconductor memory structure 100, another dielectric structure 122 may be formed. In various embodiments, the dielectric structure 122 may be formed by way of one or more deposition processes (e.g., ALD, CVD, PECVD, or the like), followed by a planarization, such that the dielectric structure 122 obtains a flush and even surface. In some embodiments, the dielectric structure 122 includes dielectric materials same as those used in the BEOL interconnect structure. In some embodiments, the dielectric structure 122 may be a part of the IMD structure. The IMD structure may include one or more dielectric layers, and the dielectric layer may include silicon oxide, silicon nitride, carbon doped silicon dioxide, BSG, PSG, BPSG, FSG, USG, a porous dielectric material, or the like. In some embodiments, the dielectric structure 122 may include a material same as that of the dielectric structure 120.

Still referring to FIG. 2J, in some embodiments, metallization layers 124a and 124b may be formed in the dielectric structure 122. The metallization layer 124a is in contact with the source electrode 140a, and the metallization layer 124b is in contact with the drain electrode 140b.

Referring to FIG. 2J, in some embodiments, the semiconductor memory structure 100 includes the gate electrode 102, the ferroelectric layer 104 over the gate electrode 102, the multilayered channel structure 110 over the ferroelectric layer 104, the source electrode 140a and the drain electrode 140b over the ferroelectric layer 104, the first multilayered structure 130a between the source electrode 140a and the multilayered channel structure 110, and the second multilayered structure 130b between the drain electrode 140b and the multilayered channel structure 110. Further, the first multilayered structure 130a surrounds the source electrode 140a from a plan view or a top view, and the second multilayered structure 130b surrounds the drain electrode 140b from the plan view or the top view, as shown in FIG. 8.

In some embodiments, the multilayered channel structure 110 includes the high Nd carrier channel layer 112 and the low Nd carrier channel layer 114. Further, the high Nd carrier channel layer 112 is between the low Nd carrier channel layer 114 and the ferroelectric layer 104. In some embodiments, the thickness of the high Nd carrier channel layer 112 and the thickness of the low Nd carrier channel layer 114 are the same, as shown in FIG. 2J. In some embodiments, the multilayered channel structure 110 helps to increase mobility and on current.

In some embodiments, by adjusting the forming of the high Nd carrier channel layer 112 and the low Nd carrier channel layer 114, the thickness of the high Nd carrier channel layer 112 is caused to be greater than the thickness of the low Nd carrier channel layer 114, as shown in FIG. 3.

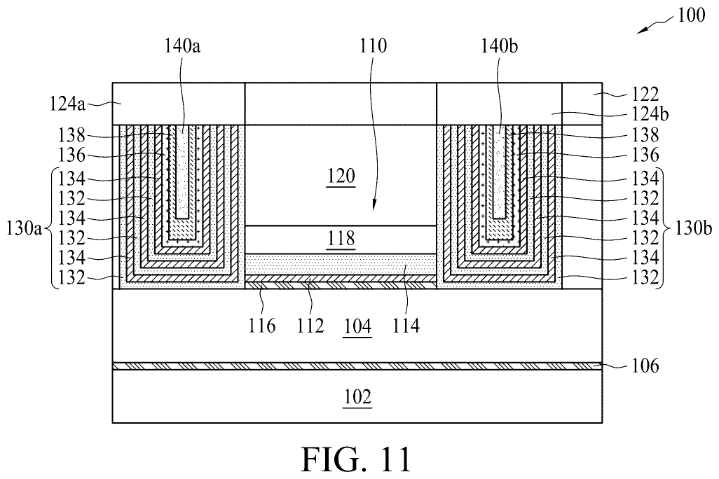

In some embodiments, by adjusting the forming of the high Nd carrier channel layer 112 and the low Nd carrier channel layer 114, the thickness of the high Nd carrier channel layer 112 is caused to be less than the thickness of the low Nd carrier channel layer 114, as shown in FIG. 11.

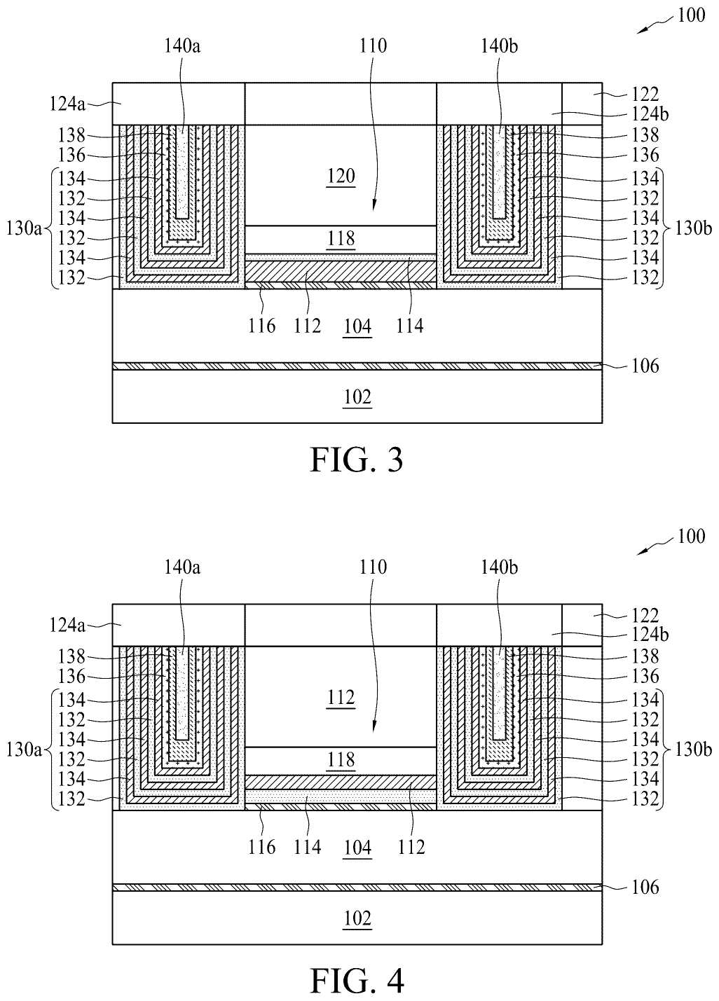

In some embodiments, by adjusting the forming of the high Nd carrier channel layer 112 and the low Nd carrier channel layer 114, the low Nd carrier channel layer 114 can be formed between the high Nd carrier channel layer 112 and the ferroelectric layer 104, as shown in FIG. 4. In such embodiments, the thickness of the high Nd carrier channel layer 112 and the thickness of the low Nd carrier channel layer 114 may be similar. In alternative embodiments, the thickness of the high Nd carrier channel layer 112 is greater than the thickness of the low Nd carrier channel layer 114, though not shown.

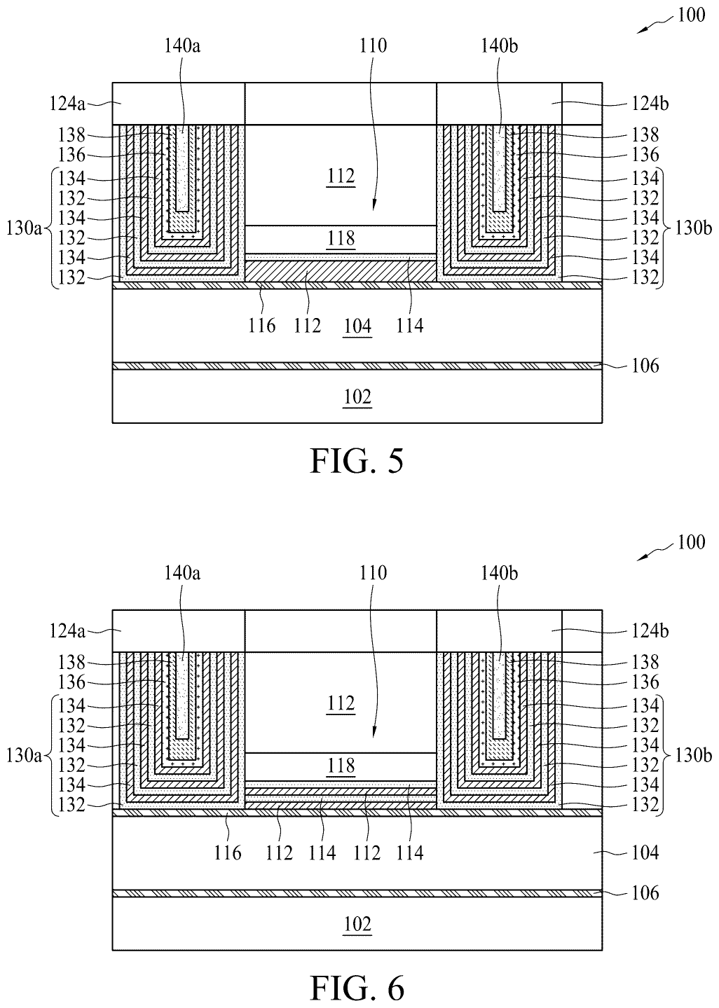

In some embodiments, due to adjustments to the patterning of the cap layer 118, the low Nd carrier channel layer 114 and the high Nd carrier channel layer 112, the interface layer 116 may be left in place over the ferroelectric layer 104, as shown in FIG. 5. In such embodiments, the ferroelectric layer 104 is protected by the interface layer 116 during the forming of the trenches 121a and 121b.

In some embodiments, the high Nd carrier channel layer 112 and the low Nd carrier channel layer 114 may be periodically formed such that the multilayered channel structure 110 includes a plurality of pairs of the high and low Nd carrier channel layers 112 and 114, as shown in FIG. 6. In such embodiments, the semiconductor memory structure 100 with multiple channels is obtained.

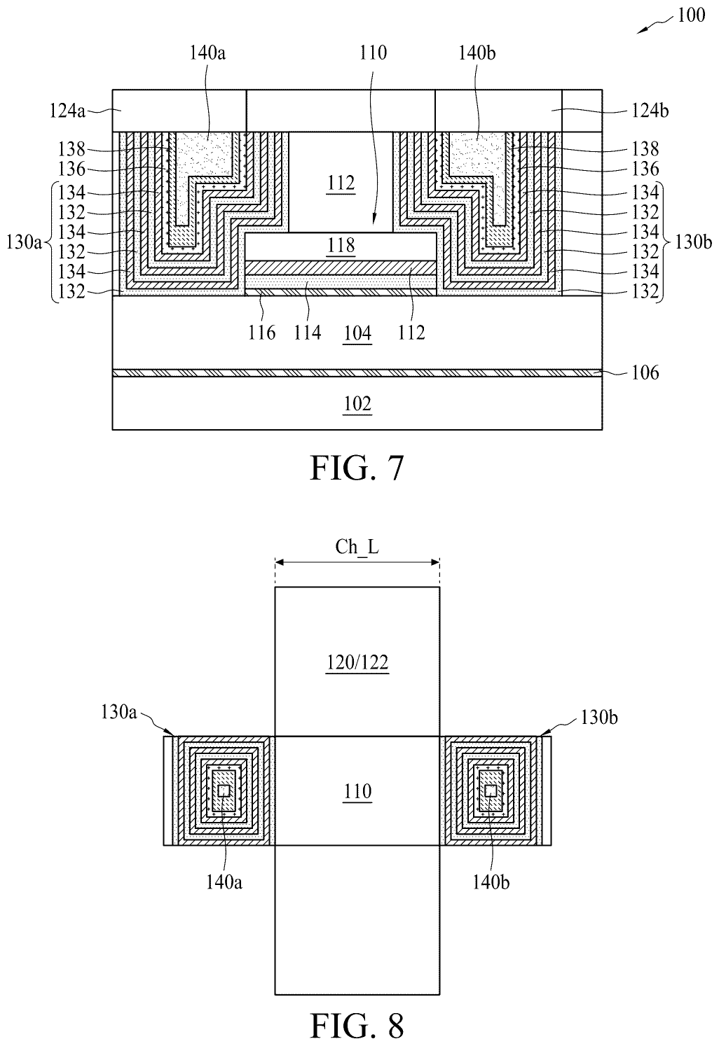

In some embodiments, the first and second multilayered structures 130a and 130b may be formed over the multilayered channel structure 110, as shown in FIG. 7. In such embodiments, sidewalls and portions of the cap layer 118 may be in contact with the first multilayered structure 130a and the second multilayered structure 130b.

In some embodiments, each of the first multilayered structure 130a and the second multilayered structure 130b includes the first semiconductor layer 132 and the second semiconductor layer 134 alternately arranged. An Nd carrier concentration of each first semiconductor layer 132 is different from an Nd carrier concentration of each second semiconductor layer 134. In some embodiments, the Nd carrier concentration of the first semiconductor layer 132 is less than the Nd carrier concentration of the second semiconductor layer 134. Therefore, each of the first multilayered structure 130a and the second multilayered structure 130b can be described as having a plurality of high Nd carrier channel layers 134 and a plurality of low Nd carrier channel layers 132 alternately arranged. The low Nd carrier channel layers 132 and the high Nd carrier channel layers 134 in each of the first multilayered structure 130a and the second multilayered structure 130b work together to form quantum wells, thereby raising an electron confinement effect in the source and drain regions. The mobility and the on current may be further increased due to the electron confinement effect.

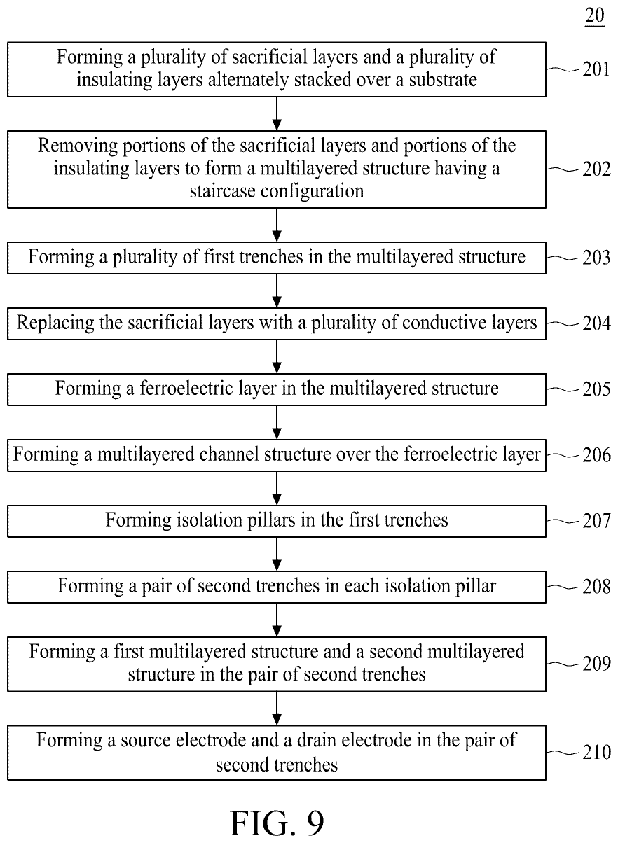

FIG. 9 is a flowchart representing a method for forming a 3D semiconductor memory structure 20 in accordance with aspects of the present disclosure. The method 20 includes a number of operations (201, 202, 203, 204, 205, 206, 207, 208, 209 and 210). The method 20 will be further described according to one or more embodiments. It should be noted that the operations of the method 20 may be rearranged or otherwise modified within the scope of the various aspects. It should be further noted that additional processes may be provided before, during, and after the method 20, and that some other processes may be only briefly described herein. Thus, other implementations are possible within the scope of the various aspects described herein.

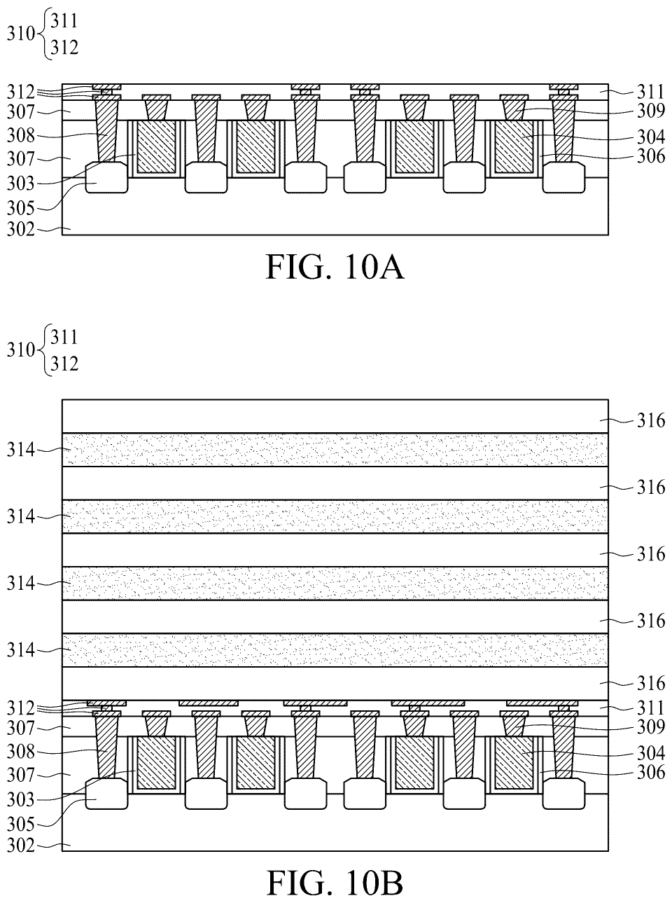

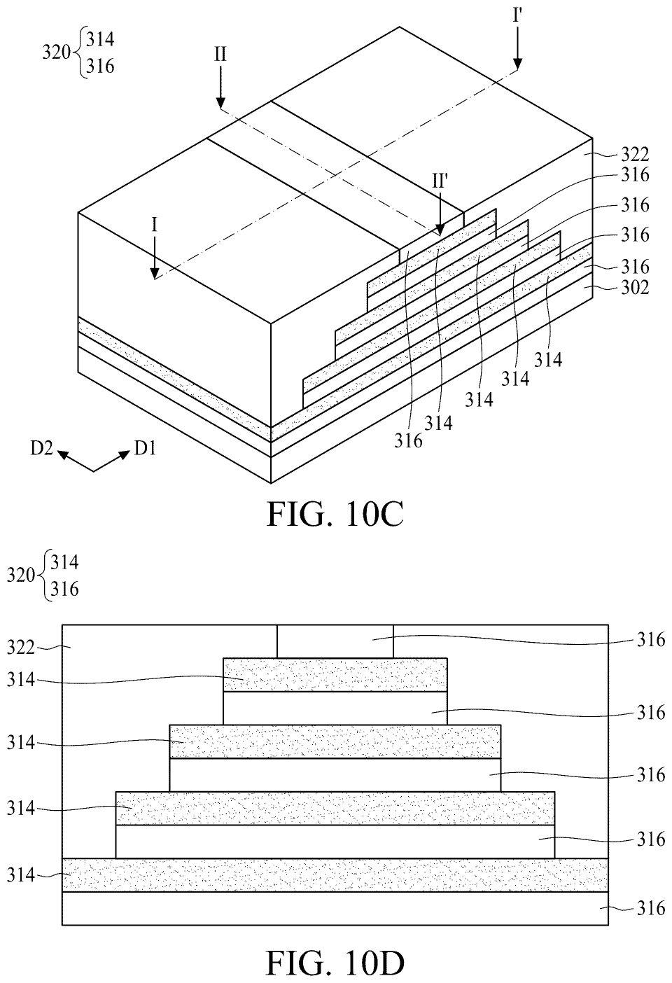

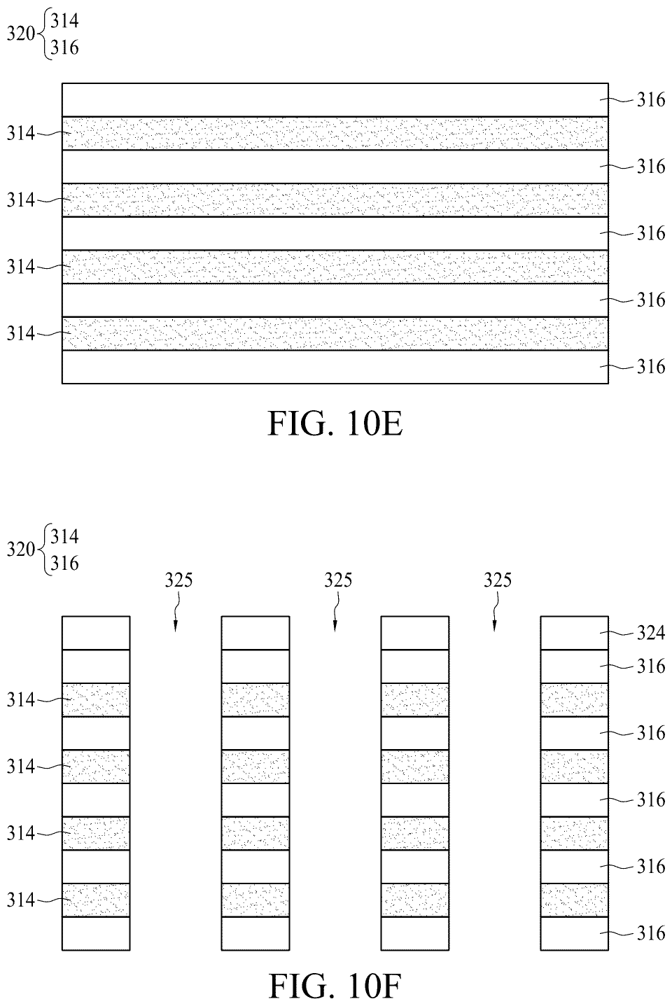

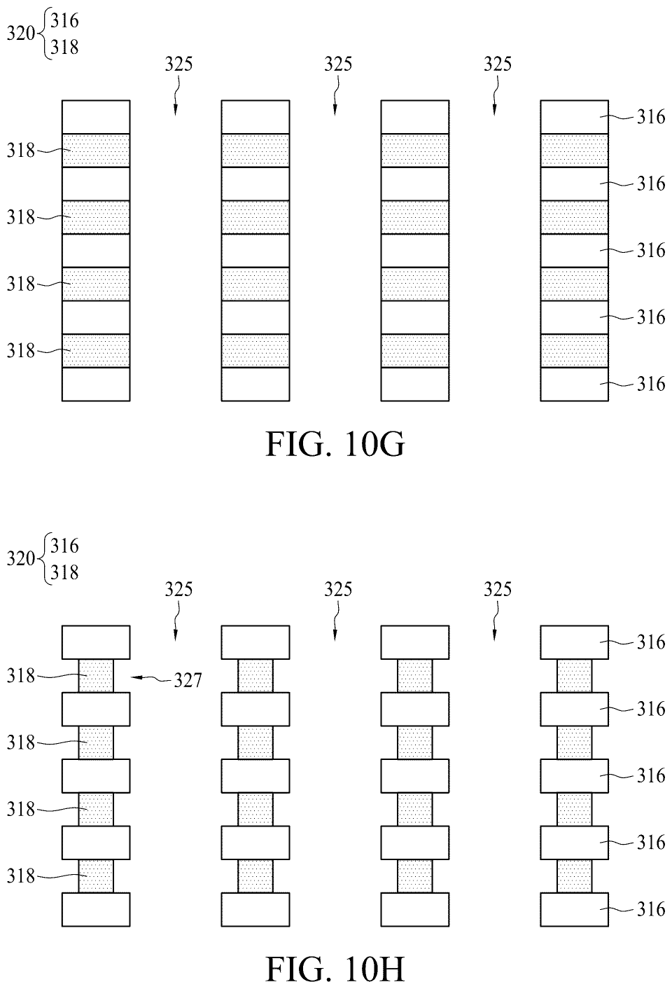

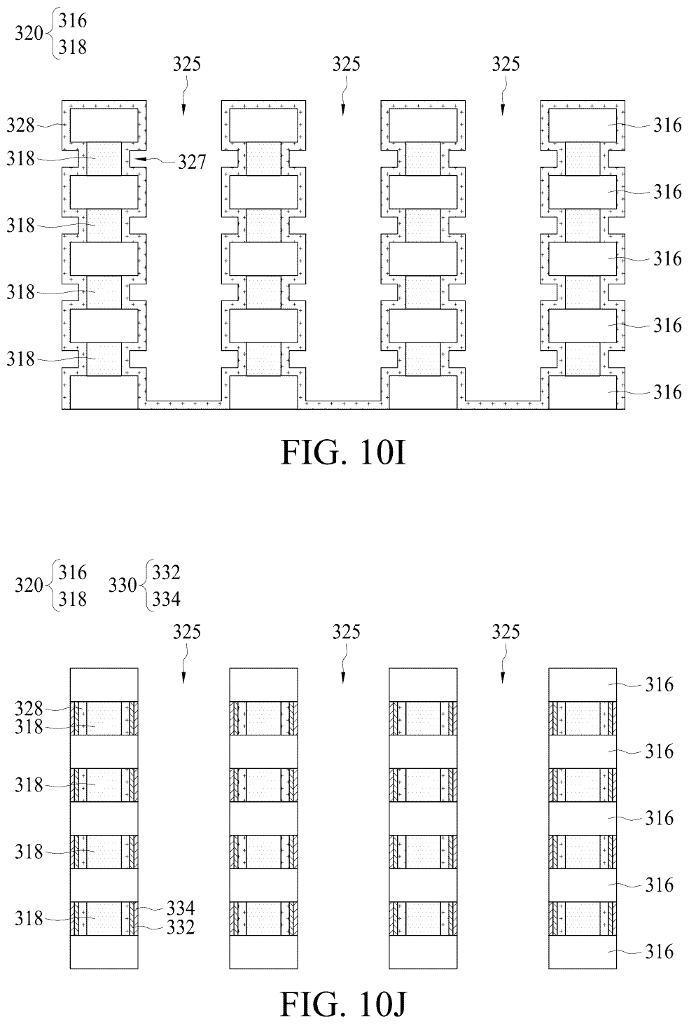

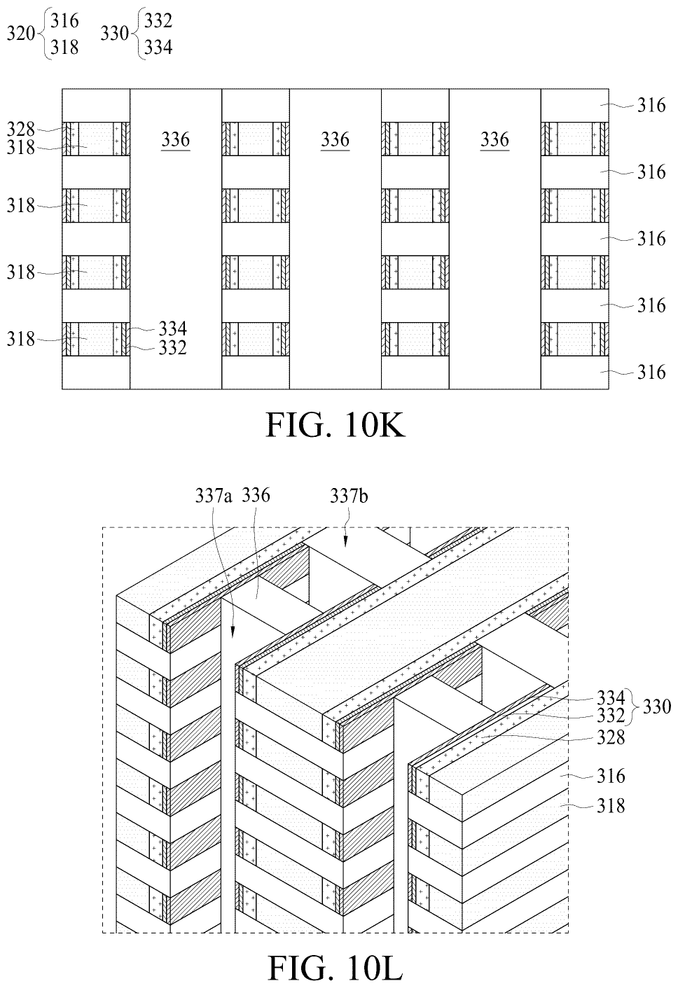

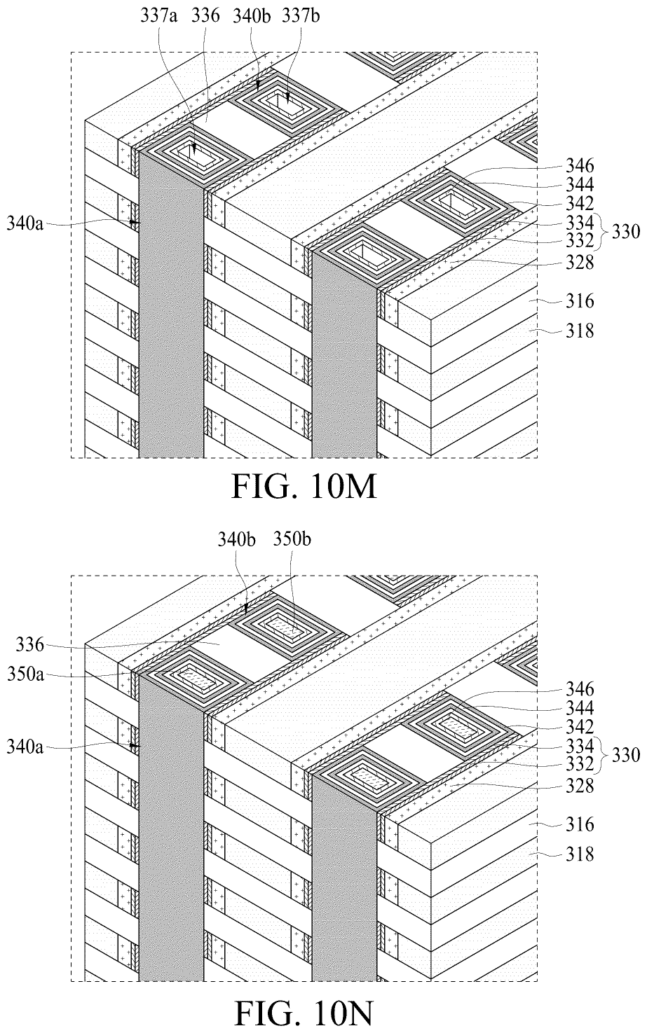

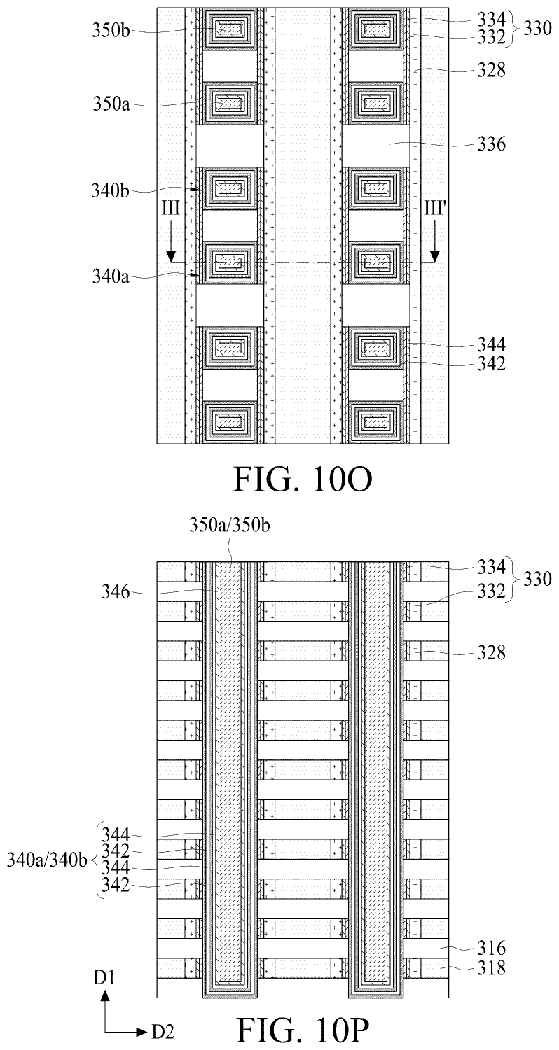

In some embodiments, in operation 201, a plurality of sacrificial layers and a plurality of insulating layers are alternately stacked over a substrate. Referring to FIG. 10A, in some embodiments, a substrate 302 is received or provided. The substrate 302 may be a semiconductor substrate, such as a bulk semiconductor, a SOI substrate, or the like, and may be doped (e.g., with a p-type or an n-type dopant) or undoped. The substrate 302 may be an integrated circuit die, such as a logic die, a memory die, an ASIC die, or the like. The substrate 302 may be a complementary metal oxide semiconductor (CMOS) die and may be referred to as a CMOS under array (CUA). The substrate 302 may be a wafer, such as a silicon wafer. Generally, a SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate, may also be used.

In some embodiments, circuits may be formed over the substrate 302. The circuits include transistors formed over the substrate 302. The transistor may include gate dielectric layers 303, gate electrodes 304 over the gate dielectric layers 303, and source/drain regions 305 disposed in the substrate 302 on opposite sides of the gate dielectric layers 303 and the gate electrodes 305. Spacers 306 are formed along sidewalls of the gate dielectric layers 303 and separate the source/drain regions 305 from the gate electrodes 304 by appropriate lateral distances. The transistors may include fin field effect transistors (FinFETs), nanostructure (e.g., nanosheet, nanowire, gate-all-around, or the like) FETs (nano-FETs), planar FETs, the like, or combinations thereof, and may be formed by gate-first processes or gate-last processes. Although FIG. 10A shows transistors formed over the substrate 302, other active devices (e.g., diodes or the like) and/or passive devices (e.g., capacitors, resistors, or the like) may also be formed as part of the circuits. In some embodiments, the circuits may be formed by a front-end-of-line (FEOL) process.

An inter-layer dielectric (ILD) 307 may be formed over the substrate 302. Connecting structures 308 and 309 are disposed in and extend through the ILD 307. The connecting structures 308 are coupled to the source/drain regions 305, and the connecting structures 309 are coupled to the gate electrodes 304. In some embodiments, the ILD 307 and the connecting structures 308 and 309 may be formed by a middle-end-of-line (MEOL) process.

An interconnect structure 310 may be formed over the substrate 302. The interconnect structure 310 includes, for example, one or more stacked dielectric layers 311 and conductive features 312 formed in the one or more dielectric layers 311, for example. The interconnect structure 310 may be electrically connected to the connecting structures 308 and 309 to form functional circuits. In some embodiments, the functional circuits formed by the interconnect structure 310 may include logic circuits, memory circuits, sense amplifiers, controllers, input/output circuits, image sensor circuits, the like, or combinations thereof. In some embodiments, the interconnect structure 310 may be formed by a BEOL process.

Referring to FIG. 10B, the plurality of sacrificial layers 314 and the plurality of insulating layers 316 are formed over the substrate 302. Further, in some embodiments, the sacrificial layers 314 and the insulating layers 316 are alternately arranged with the insulating layers 316 formed as a bottommost layer and a topmost layer. In some embodiments, any number of intermediate layers may be disposed between the substrate 302 and the bottommost insulating layer 316. For example, one or more interconnect layers including conductive features in insulating layers (e.g., low-k dielectric layers) may be disposed between the substrate 302 and the bottommost insulating layer 316. In some embodiments, the conductive features may be patterned to provide power, ground, and/or signal lines for the active devices on the substrate 302 and/or the 3D semiconductor memory structure to be formed. In some embodiments, one or more interconnect layers including conductive features in insulating layers (e.g., low-k dielectric layers) may be disposed over the topmost insulating layer 316. Additionally, in some other embodiments, at least one of the topmost and bottommost layers is the sacrificial layer 314.

In some embodiments, the sacrificial layers 314 may include dielectric materials, such as silicon oxide, silicon nitride, silicon oxynitride, combinations thereof, or the like. The insulating layers 316 may include insulating materials, such as silicon oxide, silicon nitride, silicon oxynitride, combinations thereof, or the like. The sacrificial layers 314 and the insulating layers 316 include different materials with different etching selectivities. In some embodiments, the sacrificial layers 314 include silicon nitride, and the insulating layers 316 include silicon oxide. Each of the sacrificial layers 314 and the insulating layers 316 may be formed using, for example, physical vapor deposition (PVD), CVD, ALD, PECVD, or the like. Additionally, although FIG. 10B illustrates numbers of the sacrificial layers 314 and the insulating layers 316, other embodiments may include different numbers of the sacrificial layers 314 and the insulating layers 316.

Referring to FIGS. 10C and 10D, wherein FIG. 10D is a cross-sectional view taken along line I-I′ of FIG. 10C, in some embodiments, in operation 202, portions of the sacrificial layers 314 and portions of the insulating layers 316 are removed to form a multilayered structure 320 having a staircase configuration. To simply the figures, elements formed by the FEOL and MEOL processes and the interconnect structure 310 are omitted from FIG. 10D. As shown in FIGS. 10C and 10D, in such embodiments, portions of each of the sacrificial layers 314 are exposed. In some embodiments, after the forming of the multilayered structure 320, an inter-metal dielectric (IMD) structure 322 is deposited over the multilayered structure 320. The IMD structure 322 may be formed of a dielectric material, and may be deposited by any suitable method, such as CVD, PECVD, flowable CVD (FCVD), or the like. The dielectric materials may include phospho-silicate glass (PSG), boro-silicate glass (BSG), boron-doped phospho-silicate glass (BPSG), undoped silicate glass (USG), or the like. In some embodiments, the IMD structure 322 may include an oxide (e.g., silicon oxide or the like), a nitride (e.g., silicon nitride or the like), a combination thereof, or the like. Other dielectric materials formed by any acceptable process may be used. As shown in FIG. 10D, the IMD structure 322 extends along sidewalls of the sacrificial layers 314 and sidewalls of the insulating layers 316. The IMD structure 322 may contact top surfaces of the sacrificial layers 314. In some embodiments, a top surface of the IMD structure 322 and a top surface of the multilayered structure 320 are level, as shown in FIGS. 10C and 10D.

Please refer to FIGS. 10E and 10F, wherein FIG. 10E is a cross-sectional view taken along a line II-II′ of FIG. 10C, and FIG. 10F illustrates a stage subsequent to that shown in FIG. 10D. In operation 203, a plurality of trenches 325 are formed in the multilayered structure 320. In some embodiments, operation 203 may include further operations. For example, in some embodiments, a patterned hard mask 324 is formed over the multilayered structure 320. Suitable etch operations, such as a dry etch (e.g., a reactive ion etch (RIE), a neutral beam etch (NBE), or the like), a wet etch, the like, or a combination thereof, may be performed to etch the multilayered structure 320 through the patterned hard mask 324, thereby forming the plurality of trenches 325 extending through the multilayered structure 320. As shown in FIG. 10F, the sacrificial layers 314 and the insulating layers 316 are exposed through sidewalls of each trench 325.

Referring to FIG. 10G, in operation 204, the sacrificial layers 314 are replaced with a plurality of conductive layers 318. In some embodiments, the sacrificial layers 314 exposed through the sidewalls of the trenches 325 are removed using an suitable etch operation such as, for example but not limited thereto, a wet etching process, a dry etching process or both. Thereafter, the conductive layers 318 are formed to fill spaces between adjacent insulating layers 316. In some embodiments, the conductive layers 318 may include Ru, Co, Cu, Al, Ni, Au, or Ag. In some embodiments, one or more layers, such as a liner, may be formed prior to the forming of the conductive layers 318. In some embodiments, the liner may include metal nitride, such as TIN, TaN, WN, HIN, zirconium nitride (ZrN), or the like. In some embodiments, the conductive layer 318 may be formed by a suitable deposition process such as CVD, PVD, ALD, PECVD, or the like. In some embodiments, an etch operation may be performed to remove superfluous material such that the conductive layers 318 remain in the spaces between the adjacent insulating layers 316, and the conductive layers 318 and the insulating layers 316 are still exposed through the sidewalls of the trenches 325, as shown in FIG. 10G.

In operation 205, a ferroelectric layer is formed in the multilayered structure 320. In some embodiments, operation 205 may include further operations. For example, referring to FIG. 10H, in some embodiments, the conductive layers 318 of the multilayered structure 320 are recessed, such that a recess 327 is formed between the two adjacent insulating layers 316. As shown in FIG. 10H, the recesses 327 are coupled to (e.g., in spatial communication with) the corresponding trench 325. In some embodiments, ends of the conductive layers 318 are recessed by about 1 nanometer to about 10 nanometers with respect to ends of the insulating layers 316 exposed through the trench 325. In some embodiments, the conductive layers 318 are recessed using a suitable removal technique, such as a lateral etching. The etching may include a dry etch (e.g., RIE, NBE, or the like), a wet etch, the like, or a combination thereof. In some embodiments, upon completion of the recessing process, the trenches 325 have curving sidewalls. For example, the ends of the insulating layers 316 protrude from the ends of the remaining conductive layers 318.

Referring to FIG. 10I, a ferroelectric layer 328 is formed within each of the recesses 327 and the trenches 325. In some embodiments, one or more layers such as an interface layer, may be formed prior to the forming of the ferroelectric layer 328, though not shown. In some embodiments, a material of the interface layer and a material of the ferroelectric layer 328 may be similar to materials of other interface and ferroelectric layers described above; therefore, the repeated descriptions are omitted. In some embodiments, the ferroelectric layer 328 is conformally and continuously formed on the top and sidewalls of the multilayered structure 320. Further, the ferroelectric layer 328 is conformally formed in the trenches 325 along the curving sidewalls and conformally formed in the recesses 327, along a top surface of the topmost insulating layer 316, and along bottom surfaces of the trenches 325. In some embodiments, a method of forming the ferroelectric layer 328 includes performing a suitable deposition technique, such as CVD, PVD, ALD, PECVD, or the like.

In operation 206, a multilayered channel structure 330 is formed over the ferroelectric layer 328. In some embodiments, operation 206 may include further operations. For example, as shown in FIG. 10J, a first channel layer 332 and a second channel layer 334 may be sequentially formed over the ferroelectric layer 328. In some embodiments, one or more layers, such as an interface layer, may be formed prior to the forming of the first channel layer 332, though not shown. In some embodiments, a material of the interface layer may be similar to materials of the interface layers described above; therefore, repeated descriptions are omitted. In some embodiments, materials of the first channel layer 332 and the second channel layer 334 may be similar to the materials of the high Nd carrier channel layer 112 and the low Nd carrier channel layer 114; therefore, repeated descriptions are omitted. In some embodiments, the first and second channel layers 332 and 334 are conformally and continuously formed on the top and the sidewalls of the multilayered structure 320. Further, the first and second channel layers 332 and 334 are formed conformally in the trenches 325 along the curving sidewalls and fill the recesses 327, along the top surfaces of the topmost insulating layer 316, and along the bottom surfaces of the trenches 325. In some embodiments, a method of forming the first and second channel layers 332 and 334 includes performing a suitable deposition technique, such as CVD, PVD, ALD, PECVD, or the like.

In some embodiments, an etch-back process is performed to remove portions of the second channel layer 334, portions of the first channel layer 332 and portions of the ferroelectric layer 328. The etch-back process may be performed to remove excess material from the sidewalls of the insulating layers 316 and/or the bottom surfaces of the trenches 325. Acceptable etch-back processes include a dry etch (e.g., RIE, NBE, or the like), a wet etch, the like, or a combination thereof. The etching may be anisotropic. Accordingly, the ferroelectric layer 328 and the multilayered channel structures 330 filling the recess 327 are obtained. As shown in FIG. 10J, the multilayered channel structures 330 are separated from the conductive layers 318 by the ferroelectric layer 328.

Referring to FIG. 10K, in operation 207, isolation pillars 336 are formed in the trenches 325. In some embodiments, the trenches 325 are filled with an insulating material, which may include, for example but not limited thereto, silicon oxide, silicon nitride, silicon oxynitride, or the like. The insulating material may be formed by CVD, PVD, ALD, PECVD, or the like. A planarization process (e.g., a CMP, an etch-back process, or the like) may be performed to remove excess portions of the insulating material to expose the top surfaces of the multilayered structure 320 (i.e., the top surface of the topmost insulating layer 316). In some embodiments, top surfaces of the isolation pillars 336 may be level with the top surfaces of the multilayered structure 320.

Referring to FIG. 10L, in operation 208, a pair of trenches 337a and 337b are formed in each isolation pillar 336. In some embodiments, the insulating layers 316, the multilayered channel structures 330, and the isolation pillars 336 are exposed through sidewalls of each of the trenches 337a and 337b.

Referring to FIG. 10M, in operation 209, a first multilayered structure 340a is formed in the trench 337a and a second multilayered structure 340b is formed in the trench 337b. In some embodiments, a plurality of semiconductor layers 342 and a plurality of semiconductor layers 344 are periodically formed in the pair of trenches 337a and 337b. In some embodiments, the semiconductor layer 342 is in contact with the multilayered channel structure 330, exposed portions of the isolation pillars 336, and exposed portions of the insulating layers 316. In some embodiments, the semiconductor layer 342 is also formed in contact with the ferroelectric layer 328. The semiconductor layers 342 and 344 may include materials same as those of the semiconductor layers 132 and 134; therefore, details thereof are omitted for brevity.

Please refer to FIGS. 10N to 10P, wherein FIG. 100 is a top view of FIG. 10N, and FIG. 10P is a cross-sectional view taken from a line III-III′ of FIG. 100. In some embodiments, in operation 210, a source electrode 350a is formed in the trench 337a and a drain electrode 350b is formed in the trench 337b. In some embodiments, operation 209 and operation 210 may performed together. For example, in some embodiments, after the forming of the semiconductor layers 342 and the semiconductor layers 344, a conductive material is formed to fill the trenches 337a and 337b. In some embodiments, a barrier layer 346 may be formed prior to the forming of the conductive material. The barrier layer 346 may include a material same as that of the barrier layer 138; therefore, such details are omitted. In some embodiments, the conductive material may include metals such as TiN, Mo, W, or Al, but the disclosure is not limited thereto.

In some embodiments, a planarization is performed to remove superfluous material, thereby forming the source electrode 350a and the first multilayered structure 340a in the trench 337a, and the drain electrode 350b and the second multilayered structure 340b in the trench 337b. Further, the first multilayered structure 340a, the source electrode 350a, the second multilayered structure 340b and the drain electrode 350b are formed simultaneously. In some embodiments, the first multilayered structure 340a surrounds a bottom and sidewalls of the source electrode 350a, and the second multilayered structure 340b surrounds a bottom and sidewalls of the drain electrode 350b. Accordingly, a 3D semiconductor memory structure 300 is formed.

Referring to FIGS. 10N to 10P, the 3D semiconductor memory structure 300 includes the plurality of conductive layers 318 and the plurality of insulating layers 316 alternately stacked in a first direction D1. The conductive layers 318 serve as gate layers. Further, each gate layer 318 and each insulating layer 316 extend in a second direction D2 different from the first direction D1. The 3D semiconductor memory structure 300 further includes the source electrode 350a and the drain electrode 350b extending in the first direction D1. The 3D semiconductor memory structure 300 further includes the ferroelectric layer 328 between the source electrode 350a and the plurality of gate layers 316, and between the drain electrode 350b and the plurality of gate layers 316. The 3D semiconductor memory structure 300 further includes the multilayered channel structure 330 between the ferroelectric layer 328 and the source electrode 350a, and between the ferroelectric layer 328 and the drain electrode 350b. Further, the 3D semiconductor memory structure 300 includes the first multilayered structure 340a surrounding the source electrode 350a and separating the source electrode 350a from the multilayered channel structure 330, and the second multilayered structure 340b surrounding the drain electrode 350b and separating the drain electrode 350b from the multilayered channel structure 330.

Referring to FIG. 100, the first multilayered structure 340a surrounds the source electrode 350a from a plan view or a top view, and the second multilayered structure 340b surrounds the drain electrode 350b from the plan view or the top view.

The multilayered channel structure 330 may include the first channel layer 332 and the second channel layer 334. An Nd carrier concentration of the first channel layer 332 is different from an Nd carrier concentration of the second channel layer 334. In some embodiments, the Nd carrier concentration of the first channel layer 332 is greater than the Nd carrier concentration of the second channel layer 334. Therefore, the multilayered channel structure 330 can be described as having a high Nd carrier channel layer 332 and a low Nd carrier channel layer 334. In some embodiments, the high Nd carrier channel layer 332 is between the low Nd carrier channel layer 334 and the ferroelectric layer 328. In some embodiments, a thickness of the high Nd carrier channel layer 332 and the thickness of the low Nd carrier channel layer 334 are the same. In some embodiments, the thickness of the high Nd carrier channel layer 332 is greater than the thickness of the low Nd carrier channel layer 334. In some embodiments, the multilayered channel structure 330 helps to increase a mobility and an on current.

In some embodiments, the thickness of the high Nd carrier channel layer 332 is greater than the low Nd carrier channel layer 334.

In some embodiments, by adjusting formation process of the high Nd carrier channel layer 332 and the low Nd carrier channel layer 334, the multilayered channel structure 330 of the 3D semiconductor memory structure 300 may have the low Nd carrier channel layer 334 disposed between the high Nd carrier channel layer 332 and the ferroelectric layer 328. In such embodiments, the thickness of the high Nd carrier channel layer 332 and the thickness of the low Nd carrier channel layer 334 may be same. In some other embodiments, the thickness of the low Nd carrier channel layer 334, which is between the high Nd carrier channel layer 332 and ferroelectric layer 328, is less than the thickness of the high Nd carrier channel layer 332, though not shown.

In some embodiments, the high Nd carrier channel layer 332 and the low Nd carrier channel layer 334 can be periodically formed. In such embodiments, the multilayered channel structure 330 may include the pairs of high Nd carrier channel layer 332 and the low Nd carrier channel layer 334. In such embodiments, the 3D semiconductor memory structure 300 includes multiple channels.

In some embodiments, the first and second multilayered structures 340a and 340b may be formed adjacent to the multilayered channel structure 330. Further, the first and second multilayered structures 340a and 340b are separated from each other by the isolation pillar 336, which is disposed between the first multilayered structure 340a and the second multilayered structure 340b. In some embodiments, each of the first multilayered structure 340a and the second multilayered structure 340b includes the first semiconductor layers 342 and the second semiconductor layers 344 alternately arranged. An Nd carrier concentration of each first semiconductor layer 342 is different from an Nd carrier concentration of each second semiconductor layer 344. In some embodiments, the Nd carrier concentration of the first semiconductor layer 342 is less than the Nd carrier concentration of the second semiconductor layer 344. Therefore, each of the first multilayered structure 340a and the second multilayered structure 340b can be described as having a plurality of high Nd carrier channel layers 344 and a plurality of low Nd carrier channel layers 342 alternately arranged. The low Nd carrier channel layers 342 and the high Nd carrier channel layers 344 in each of the first multilayered structure 340a and the second multilayered structure 340b work together to form quantum wells, thereby raising an electron confinement effect in the source and drain regions. The mobility and the on current may be further increased due to the electron confinement effect.

Accordingly, the present disclosure provides a semiconductor memory structure and a method for forming the same. In some embodiments, the semiconductor memory structure may be a ferroelectric memory structure formed in a BEOL interconnect structure. In some embodiments, the semiconductor memory structure may include a multilayered channel structure having at least a high Nd carrier channel layer and a low Nd carrier channel layer. A mobility is therefore improved to mitigate defect issues, and thus an on current (Ion) is increased by the multilayered channel structure.

In some embodiments, the semiconductor memory structure may include the multilayered structures surrounding a source electrode and a drain electrode. The multilayered structure includes a plurality of high Nd carrier channel layers and a plurality of low Nd carrier channel layers, and serves as a quantum well and as a part of the channel region and improves an electron confinement effect on the source/drain regions. Accordingly, the mobility and the on current are further increased.

In some embodiments, a semiconductor memory structure is provided. The semiconductor memory structure includes a gate electrode, a ferroelectric layer over the gate electrode, a channel structure over the ferroelectric layer, a source electrode and a drain electrode over the ferroelectric layer, a first multilayered structure, and a second multilayered structure. The first multilayered structure is disposed between the source electrode and the channel structure, and the second multilayered structure is disposed between the drain electrode and the channel structure. The channel structure includes a first channel layer over the ferroelectric layer and a second channel layer between the first channel layer and the ferroelectric layer. A donor carrier concentration of the first channel layer is different from a donor carrier concentration of the second channel layer.

In some embodiments, a semiconductor memory structure is provided. The semiconductor memory structure includes a plurality of gate layers and a plurality of dielectric layers alternately stacked in a first direction, a source electrode and a drain electrode extending in the first direction, a ferroelectric layer, a channel structure, a first multilayered structure, and a second multilayered structure. The gate layers and the dielectric layers extend in a second direction different from the first direction. The ferroelectric layer is disposed between the source electrode and the plurality of gate layers, and between the drain electrode and the plurality of gate layers. The channel structure is disposed between the ferroelectric layer and the source electrode, and between the ferroelectric layer and the drain electrode. The channel structure includes a first channel layer and a second channel layer. The first channel layer has a first donor carrier concentration, and the second channel layer has a second donor carrier concentration different from the first donor carrier concentration. The first multilayered structure surrounds the source electrode and separates the source electrode from the channel structure. The second multilayered structure surrounds the drain electrode and separates the drain electrode from the channel structure.

In some embodiments, a method for forming a semiconductor memory structure is provided. The method includes following operations. A gate electrode is formed over a substrate. A ferroelectric layer is formed over the gate electrode. A multilayered channel structure is formed over the ferroelectric layer. A first multilayered structure and a second multilayered structure are formed adjacent to the multilayered channel structure. A source electrode and a drain electrode are formed adjacent to the multilayered channel structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure comprising:
a gate electrode;
a ferroelectric layer over the gate electrode;
a channel structure over the ferroelectric layer, wherein the channel structure comprises:
a first channel layer over the ferroelectric layer; and
a second channel layer between the first channel layer and the ferroelectric layer;
a source electrode and a drain electrode over the ferroelectric layer;
a first multilayered structure between the source electrode and the channel structure; and
a second multilayered structure between the drain electrode and the channel structure,
wherein a donor carrier concentration of the first channel layer is different from a donor carrier concentration of the second channel layer.

2. The semiconductor structure of claim 1, wherein a thickness of the first channel layer is different from a thickness of the second channel layer.

3. The semiconductor structure of claim 1, wherein a thickness of the first channel layer is equal to a thickness of the second channel layer.

4. The semiconductor structure of claim 1, further comprising a cap layer over the channel structure.

5. The semiconductor structure of claim 1, further comprising an interface layer between the channel structure and the ferroelectric layer.

6. The semiconductor structure of claim 1, wherein the first channel layer and the second channel layer are periodically stacked over the ferroelectric layer.

7. The semiconductor structure of claim 1, wherein the first multilayered structure and the second multilayered structure respectively comprise a plurality of first semiconductor layers and a plurality of second semiconductor layers alternately arranged.

8. The semiconductor structure of claim 7, wherein a donor carrier concentration of each first semiconductor layer is less than a donor carrier concentration of each second semiconductor layer.

9. The semiconductor structure of claim 1, wherein the first multilayered structure is in contact with a first sidewall of the channel structure, and the second multilayered structure is in contact with a second sidewall of the channel structure.

10. The semiconductor structure of claim 9, wherein the first multilayered structure is disposed over a first portion of the channel structure, and the second multilayered structure is disposed over a second portion of the channel structure.

11. A semiconductor structure comprising:
a plurality of gate layers and a plurality of insulating layers alternately stacked in a first direction, wherein each gate layer and each insulating layer extend in a second direction different from the first direction;
a source electrode and a drain electrode extending in the first direction;
a ferroelectric layer between the source electrode and the plurality of gate layers, and between the drain electrode and the plurality of gate layers;
a channel structure between the ferroelectric layer and the source electrode, and between the ferroelectric layer and the drain electrode, wherein the channel structure comprises:
a first channel layer comprising a first donor carrier concentration; and
a second channel layer comprising a second donor carrier concentration;
a first multilayered structure surrounding the source electrode and separating the source electrode from the channel structure; and
a second multilayered structure surrounding the drain electrode and separating the drain electrode from the channel structure,
wherein the first donor carrier concentration of the first channel layer is different from the second donor carrier concentration of the second channel layer.

12. The semiconductor structure of claim 11, wherein each of the first multilayered structure and the second multilayered structure comprises a plurality of first semiconductor layers and a plurality of second semiconductor layers alternately arranged.

13. The semiconductor structure of claim 12, wherein a donor carrier concentration of each first semiconductor layer is different from a donor carrier concentration of each second semiconductor layer.

14. The semiconductor structure of claim 11, wherein the first multilayered structure surrounds the source electrode from a top view, and the second multilayered structure surrounds the drain electrode from the top view.

15. The semiconductor structure of claim 11, further comprising an isolation pillar disposed between the first multilayered structure and the second multilayered structure.

16. A method for forming a semiconductor structure, comprising:
forming a gate electrode over a substrate;
forming a ferroelectric layer over the gate structure;
forming a multilayered channel structure over the ferroelectric layer;
forming a first multilayered structure and a second multilayered structure adjacent to the multilayered channel structure; and
forming a source electrode and a drain electrode adjacent to the multilayered channel structure.

17. The method of claim 16, wherein the forming of the multilayered channel structure further comprises:
forming a first channel layer over the ferroelectric layer;
forming a second channel layer over the first channel layer; and
patterning the first channel layer and the second channel layer to form the channel structure,
wherein a donor carrier concentration of the first channel layer is different from a donor carrier concentration of the second channel layer.

18. The method of claim 16, further comprising forming a dielectric structure over the channel structure and the ferroelectric layer.

19. The method of claim 18, wherein the forming of the first multilayered structure and the second multilayered structure comprises:
removing portions of the dielectric structure to form a first trench and a second trench;
periodically forming a first semiconductor layer and a second semiconductor layer in the first trench and the second trench; and
performing a planarization,
wherein a donor carrier concentration of each first semiconductor layer is different from a donor carrier concentration of each second semiconductor layer.

20. The method of claim 19, wherein the forming of the source electrode and the drain electrode further comprises:
forming a conductive material filling the first trench and the second trench; and
performing the planarization to form the first multilayered structure and the source electrode in the first trench, and the second multilayered structure and the drain electrode in the second trench,
wherein the first multilayered structure surrounds a bottom and sidewalls of the source electrode, and the second multilayered structure surrounds a bottom and sidewalls of the drain electrode.
